(19) United States
(12) Patent Application Publication
(10) Pub. No.: US 2026/0309658 A1
(43) Pub. Date: Oct. 8, 2026

(54) SUBSTRATE INSPECTION APPARATUS

(71) Applicant: SAMSUNG ELECTRONICS CO., LTD., Suwon-si (KR)

(72) Inventors: Eunhyuk CHOI, Suwon-si (KR); Chabum LEE, College Station, TX (US); Myungjun LEE, Suwon-si (KR); Taejoong KIM, Suwon-si (KR); Inkeun BAEK, Suwon-si (KR)

(73) Assignees: SAMSUNG ELECTRONICS CO., LTD., Suwon-si (KR); THE TEXAS A&M UNIVERSITY SYSTEM, College Station, TX (US)

(21) Appl. No.: 19/576,589

(22) Filed: Mar. 24, 2026

(30) Foreign Application Priority Data
Apr. 8, 2025 (KR) 10-2025-0045668

(51) Int. Cl. G01N 27/02

(52) U.S. Cl. CPC G01N 27/02

(57) ABSTRACT

Provided is a substrate inspection apparatus configured to inspect a substrate, the substrate inspection apparatus including a first probe on an upper portion of the substrate, a second probe on a lower portion of the substrate opposite to the first probe, the second probe being configured to have a polarity opposite to that of the first probe, and an impedance analyzer configured to measure an impedance by at least one of a current applied to the first probe and the second probe and a voltage applied to the first probe and the second probe.

### CROSS-REFERENCE TO RELATED APPLICATION

This application claims priority to and the benefit of Korean Patent Application No. 10-2025-0045668 filed with the Korean Intellectual Property Office on Apr. 8, 2025, the disclosure of which is incorporated herein in its entirety by reference.

### BACKGROUND

### 1. Field

Embodiments of the present disclosure relate to a substrate inspection apparatus, and more particularly, to an inspection apparatus for measuring a bonding strength of a bonding region of a substrate.

### 2. Description of the Related Art

With recent advancement of semiconductor technology, performance improvement and functional integration of various devices are becoming important research topics. One of the key technologies that enables this integration is hybrid bonding, a heterogeneous wafer bonding technology.

Specifically, by integrating devices with different functions, such as a dynamic random access memory (DRAM), a flash memory, and a logic, onto a single wafer, an interaction between devices may be optimized, manufacturing costs may be reduced, and an efficiency of the overall system may be improved.

The hybrid bonding is an advanced technology that enables a physical and electrical connection between different wafers. Specifically, the hybrid bonding provides a substrate that guarantees relatively high reliability and performance by bonding wafers of different materials with nanometer-level precision.

However, non-uniformity or defects in a bonding strength that may occur when bonding different wafers may have a serious impact on the performance of the entire device, and it may be very important to accurately evaluate the bonding strength and quality.

To evaluate the above-mentioned bonding strength and quality, a method of destroying a sample with a member such as a blade was used. However, when using such a destructive method, there is a problem of evaluating the wafer bonding strength at a limited position within the sample.

To overcome the problem, a non-destructive method such as an ultrasonic reflection method have been proposed. However, the ultrasonic reflection method has a problem in that it depends on mechanical changes caused by voids, such as air layers, existing within a bonded bonding layer between wafers. Furthermore, the ultrasonic reflection method has a problem in that it is difficult to measure the bonding strength due to a bonding film property, such as a covalent bonding state between the bonding layers, which may affect the bonding strength.

### SUMMARY

One or more embodiments provide a substrate inspection apparatus capable of indirectly analyzing a bonding strength at an arbitrary position on a substrate without destroying wafers bonded within the substrate.

One or more embodiments also provide a substrate inspection apparatus capable of indirectly analyzing a bonding strength at an arbitrary position within a substrate more precisely without destroying wafers bonded within the substrate.

One or more embodiments also provide a substrate inspection apparatus capable of directly analyzing a bonding strength within a substrate and a property of a bonding region disposed between wafers without destroying the wafers bonded within the substrate.

According to an aspect of one or more embodiments, there is provided a substrate inspection apparatus configured to inspect a substrate, the substrate inspection apparatus including a first probe on an upper portion of the substrate, a second probe on a lower portion of the substrate opposite to the first probe, the second probe being configured to have a polarity opposite to that of the first probe, and an impedance analyzer configured to measure an impedance by at least one of a current applied to the first probe and the second probe and a voltage applied to the first probe and the second probe.

According to another aspect of one or more embodiments, there is provided a substrate inspection apparatus configured to inspect a substrate, the substrate inspection apparatus including a first probe on an upper portion of the substrate and configured to include a first magnetic body having magnetism, a second probe on a lower portion of the substrate opposite to the first probe, the second probe being configured to have a second magnetic body having magnetism opposite to the magnetism of the first magnetic body, and an impedance analyzer configured to measure an impedance by at least one of a current applied to the first probe and the second probe and a voltage applied to the first probe and the second probe, wherein the first probe and the second probe are self-aligned along a same vertical axis.

According to still another aspect of one or more embodiments, there is provided a substrate inspection apparatus for inspecting a substrate, the substrate inspection apparatus including a substrate support configured to support the substrate, a first probe on an upper portion of the substrate, a second probe on a lower portion of the substrate opposite to the first probe, a polarity of the second probe being different from a polarity of the first probe, an impedance analyzer configured to apply an alternating current (AC) signal to the first probe and the second probe and detect a change in an impedance based on a frequency generated from the AC signal, and an information management and analyzer configured to compare and analyze information about a pre-secured substrate and information measured from the impedance analyzer to obtain information about a bonding layer between an upper substrate and a lower substrate included in the substrate..

### BRIEF DESCRIPTION OF DRAWINGS

Embodiments will be more clearly understood from the following detailed description taken in conjunction with the accompanying drawings in which:

FIG. 1 illustrates a perspective view of a substrate inspection apparatus according to one or more embodiments;

FIG. 2 illustrates a cross-sectional view of a substrate inspection apparatus taken along line AA′ in FIG. 1;

FIG. 3 illustrates a block diagram of an impedance analyzer according to one or more embodiments;

FIG. 4 illustrates a block diagram of an impedance analyzer according to one or more other embodiments;

FIG. 5 illustrates a cross-sectional view of a substrate inspection apparatus according to another embodiment of FIG. 2;

FIG. 6 illustrates a cross-sectional view of a substrate inspection apparatus according to another embodiment of FIG. 2;

FIG. 7 illustrates a perspective view of a substrate inspection apparatus according to one or more embodiments.

FIG. 8 illustrates a cross-sectional view of a substrate apparatus taken along line BB′ in FIG. 7;

FIGS. 9, 10, and 11 each illustrate a cross-sectional view of a substrate inspection apparatus according to another embodiment of FIG. 8;

FIG. 12 illustrates a perspective view of a substrate inspection apparatus according to one or more embodiments;

FIG. 13 illustrates a cross-sectional view of a substrate apparatus taken along line CC′ in FIG. 12;

FIG. 14 ills a block diagram of an impedance analyzer and an information management and analyzer according to one or more embodiments;

FIG. 15 illustrates a block diagram of an information management and analyzer according to one or more embodiments;

FIG. 16 illustrates a flowchart of a substrate inspection method according to one or more embodiments;

FIGS. 17 and 18 illustrate detailed flowcharts of an operation for evaluating a bonding strength of a bonding region according to one or more embodiments; and

FIGS. 19 and 20 illustrate data on bonding strength evaluation results according to a substrate inspection apparatus or a substrate inspection method according to one or more embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, plate, etc. is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

As used herein, the term “and/or” includes any and all combinations of one or more of the associated listed items. For example, an expression, “a and/or b” should be understood as including only a, only b and both a and b. As used herein, an expression “at least one of” preceding a list of elements modifies the entire list of the elements and does not modify the individual elements of the list. For example, an expression, “at least one of a, b, and c” and “at least one of a, b, or c” should be understood as including only a, only b, only c, both a and b, both a and c, both b and c, or all of a, b, and c.

Further, throughout the specification, the phrase “in a plan view” means when an object portion is viewed from above, and the phrase “in a cross-sectional view” means when a cross-section taken by vertically cutting an object portion is viewed from the side.

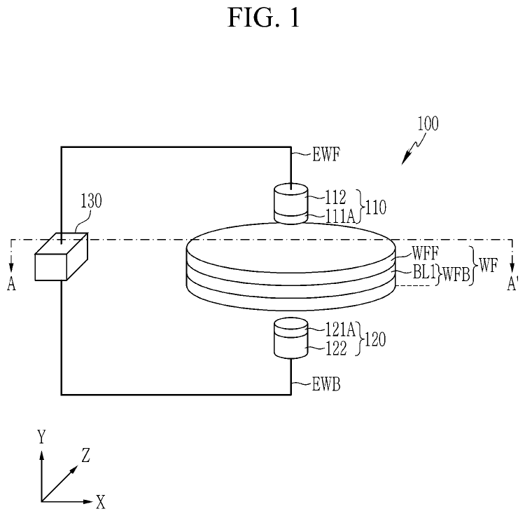

FIG. 1 illustrates a perspective view of a substrate inspection apparatus 100 according to one or more embodiments.

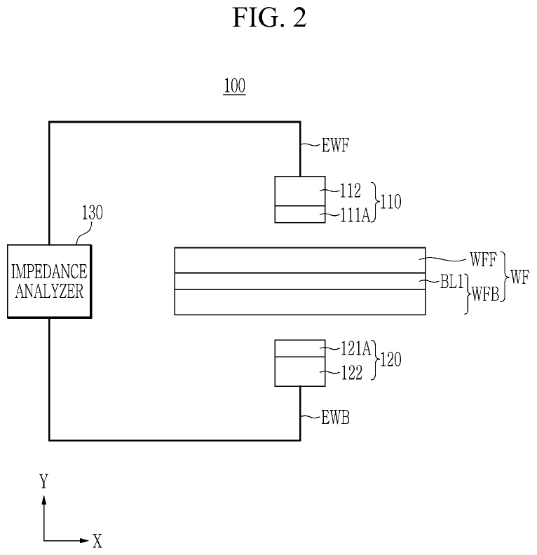

FIG. 2 illustrates a cross-sectional view of the substrate inspection apparatus 100 taken along line AA′ in FIG. 1.

Referring to FIGS. 1 and 2, the substrate inspection apparatus 100 may inspect a substrate WF including a semiconductor device. The substrate inspection apparatus 100 may include a first probe 110, a second probe 120, and an impedance analyzer 130. For example, the substrate inspection apparatus 100 according to one or more embodiments may measure a bonding strength of a bonding region between multiple substrates WFF and WFB after performing hybrid bonding, which is a process of bonding the multiple substrates WFF and WFB. In this way, the substrate inspection apparatus 100 according to one or more embodiments may operate as a metrology and inspection (MI) technology capable of evaluating characteristics of the bonding region, such as the bonding strength between the multiple substrates WFF and WFB in the substrate WF subjected to the hybrid bonding technology, at an early stage.

The substrate WF including the semiconductor device may be a substrate including a semiconductor device such as a memory chip, a processor, a sensor, a communication module, or a power management chip. The memory chip may be at least one of a DRAM, a SRAM, or a NAND Flash. The processor may be at least one of a CPU, a GPU, or an ASIC.

The sensor may be at least one of an image sensor, a temperature sensor, or a pressure sensor, and the communication module may be at least one of an RF module or a transceiver. The power management chip may be an integrated circuit such as a power management IC.

The substrate WF including a semiconductor device may include an upper substrate WFF and a lower substrate WFB. For example, the upper substrate WFF may be formed of the semiconductor device described above, and the lower substrate WFB may be formed of a semiconductor device that is the same as or different from the semiconductor device described above.

A bonding layer BL1 may provide a bonding surface to the upper substrate WFF and the lower substrate WFB, and may include, e.g., an oxide film. In FIG. 1, the bonding layer BL1, which is a bonding region between the upper substrate WFF and the lower substrate WFB, is illustrated as being arranged as a single layer on a portion of the lower substrate WFB, but embodiments are not limited thereto, and a film that functions as the bonding layer BL1 may also be placed on a lower surface of the upper substrate WFF.

The first probe 110 may be placed at an upper portion of the substrate WF. For example, the first probe 110 may include an electrode or a magnetic body. More For example, the first probe 110 may form an electric or magnetic field with the opposing second probe 120.

The second probe 120 may be placed at a lower portion of the substrate WF. For example, the second probe 120 may include an electrode or a magnetic body. For example, the second probe 120 may form an electric field or magnetic field with the opposing first probe 110.

For example, as illustrated in FIG. 1, the first probe 110 may include a first surface electrode 111A and a first electrode 112 and the second probe 120 may include a second surface electrode 121A and a second electrode 122.

For example, the first surface electrode 111A may serve and/or operate as a working electrode. The working electrode may serve and/or operate as a primary site for an electrochemical reaction, and may facilitate electrochemical transformation of the substrate WF that is a subject of analysis.

The second surface electrode 121A may serve and/or operate as a counter electrode, for example. The counter electrode may serve and/or operate to provide or consume a current, and may complete an electrical circuit in an electrochemical cell.

The first electrode 112 and the second electrode 122 may be members that fix a surface electrode or a magnetic body and assist in allowing a current or a voltage to flow between the first probe 110 and the second probe 120. For example, the first electrode 112 and the second electrode 122 may fix the surface electrode or the magnetic body in a direction facing the substrate WF, and an upper wire EWF and a lower wire EWB may be arranged in opposite directions to connect the first probe 110 and the second probe 120 to the impedance analyzer 130.

In one or more embodiments, the first electrode 112 and the second electrode 122 may be configured as conductors to facilitate a flow of current or voltage between the first probe 110 and the second probe 120. The conductors may assist in allowing an electrical signal transmitted from an impedance analyzer 130 to more easily pass through the substrate WF.

In one or more embodiments, the conductors may be formed of a material such as a metal. The conductors may have relatively low resistance, to more easily transmit an electrical signal between the first probe 110 and the second probe 120. The metal may include various metals such as, but not limited to, copper, aluminum, silver, gold, nickel, tungsten, or titanium.

In one or more embodiments, the first surface electrode 111A and the first electrode 112 may be made of a same material. When the first surface electrode 111A and the first electrode 112 are formed of the same material, the first surface electrode 111A and the first electrode 112 may be integrally formed. However, even if the first surface electrode 111A and the first electrode 112 are made of the same material, they may still exist in a separable form.

In one or more other embodiments, the first surface electrode 111A and the second electrode 112 may be made of different materials. When the first surface electrode 111A and the first electrode 112 are made of different materials, the first surface electrode 111A and the first electrode 112 may have independently separated forms. The above-mentioned content may be equally applied to the second surface electrode 121A and the second electrode 112 within a range that is not contradictory.

In one or more embodiments, the upper wire EWF and the lower wire EWB may be connected to the first probe 110 and the second probe 120 to the impedance analyzer 130. The upper wire EWF may connect between the first probe 110 and the impedance analyzer 130 to transmit a signal from the substrate WF to the impedance analyzer 130. The upper wire EWF may be a relatively highly conductive material capable of minimizing a loss of an electrical signal. For example, the upper wire EWF may be made of a metal such as copper or silver.

The lower wire EWB may connect between the second probe 120 and the impedance analyzer 130 to transmit a signal from the substrate WF to the impedance analyzer 130. The lower wire EWB may be a relatively highly conductive material capable of minimizing a loss of an electrical signal. For example, the lower wire EWB may be made of a metal such as copper or silver.

In one or more embodiments, the upper wire EWF and the lower wire EWB may be implemented in a form of cables. For example, the upper wire EWF and the lower wire EWB may be implemented in the form of cables, thereby protecting signals from external electromagnetic interference.

In this way, the first probe 110 and the second probe 120 may be members that transmit electrical signals and measure responses in an electrochemical reaction. For example, the first probe 110 and the second probe 120 may form an electric field or a magnetic field and induce movement of charges to generate electrical impedance.

The impedance analyzer 130 may apply an AC signal to the first probe 110 and the second probe 120, and may detect a change in impedance according to a frequency generated from the AC signal. For example, the impedance analyzer 130 may apply an AC voltage or AC current whose frequency changes from a lower frequency to a higher frequency to the first probe 110 and the second probe 120.

The impedance analyzer 130 may calculate and/or obtain impedance by measuring a response of current to voltage applied to the first probe 110 and the second probe 120, for example. Thereafter, by repeating the measurement while changing a frequency of the applied AC signal, the impedance at various frequencies may be measured to analyze a frequency response characteristic.

An impedance value obtained from the frequency may represent an electrical characteristic and a dynamic behavior of the substrate WF, e.g., the bonding layer BL1, through which a bonding strength of the bonding layer BL1 may be indirectly measured. For example, the impedance analyzer 130 may convert measurement information including a change in the impedance into graphics to perform electrochemical modeling. In this way, the impedance analyzer 130 may perform the electrochemical modeling using a method of visualizing the measurement information, such as electrochemical impedance spectroscopy.

In one or more embodiments, the impedance analyzer 130 may model and visualize the impedance value obtained from the frequency by at least one of a Nyquist diagram, a Bode diagram, a Cole-Cole plot, an impedance phase plot, or an admittance plot. For example, the impedance analyzer 130 may derive real and imaginary components from the measured impedance value, and may visualize them by modeling them using the Nyquist diagram. For example, the Nyquist diagram may be modeled as a graph including a semi-circle radius, and as quality of the bonding surface between the wafers becomes more ideal, contact resistance of the bonding portion may decrease, and thus a radius of the semi-circle may decrease.

In one or more embodiments, the first probe 110 and the second probe 120 may be positioned a predetermined distance apart from the substrate WF. For example, even when the first probe 110 and the second probe 120 are spaced apart from the substrate WF by a predetermined distance, an electric field may be appropriately formed between the first surface electrode 111A and the second surface electrode 121A. The impedance value may be more easily measured by the electric field, and modeling thereof may be more easily performed in the impedance analyzer 130. However, embodiments are not limited thereto, and impedance analysis may be performed while the first surface electrode 111A and the second surface electrode 121A may in contact with the substrate WF.

In this way, the first probe 110 and the second probe 120 may indirectly evaluate quality of a bonding surface between the wafers for at least some regions of the substrate WF by sequentially measuring impedance values in multiple regions of the substrate WF by a non-destructive method. As a result, an operation of performing a Fab-Out analysis on the substrate WF after the process may be eliminated, enabling immediate monitoring, which reduces a time required for process feedback and allows the substrate WF to be reused, providing cost advantages.

Furthermore, the substrate inspection apparatus according to one or more embodiments may detect a change in a bonding strength resulting from a change in physical properties of the bonding layer BL1 after a subsequent process by measuring electrical characteristics of the bonding layer BL1 in the substrate WF to measure the bonding strength.

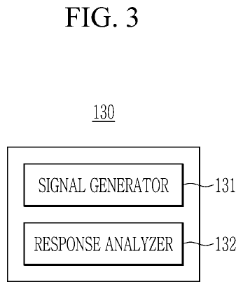

FIG. 3 illustrates a block diagram of the impedance analyzer 130 according to according to one or more embodiments.

Referring to FIG. 3, the impedance analyzer 130 may be an analyzer for performing electrochemical impedance spectroscopy, and may include a signal generator 131 and a response analyzer 132. For example, the impedance analyzer 130 may supply a voltage or a current to the first probe 110 and the second probe 120 to perform the electrochemical impedance spectroscopy and analyze impedance values measured from the first probe 110 and the second probe 120.

The signal generator 131 may generate an alternating current (AC) signal required to perform the electrochemical impedance spectroscopy. The AC signal may be, e.g., an AC voltage or AC current. For example, the signal generator 131 may inject the AC signal into the first probe 110 and the second probe 120 to measure changes in impedance at various frequencies.

The response analyzer 132 may measure the impedance value according to the frequency generated by the signal generator 131. For example, the response analyzer 132 may detect changes in impedance according to the frequency and more accurately measure values such as a size of the impedance and a phase of the impedance.

The response analyzer 132 may determine tendency of factors such as a bonding resistance value based on the impedance value. In regions where certain threshold values deviate from the tendency, it may be observed that bonding between wafers is not properly performed, resulting in relatively low bonding strength.

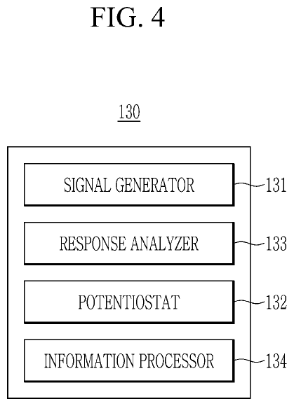

FIG. 4 illustrates a block diagram of the impedance analyzer 130 according to one or more other embodiments.

Referring to FIG. 4, in one or more embodiments, the impedance analyzer 130 may further include a potentiostat 133. The potentiostat may more accurately control and maintain the voltage or current between the first probe 110 and the second probe 120. For example, the potentiostat 133 may control the voltage or the current through mutual comparison between the first probe 110 and the second probe 120.

In one or more embodiments, the impedance analyzer 130 may further include an information processor 134. The information processor 134 may control the response analyzer 132 to process and analyze the measured impedance value for the measured impedance value to be interpretable. For example, information processor 134 may generate various plots of the impedance value through software.

In one or more embodiments, the information processor 134 may convert measurement information including changes in impedance obtained from the response analyzer 132 into a graphic to perform the electrochemical modeling. For example, the measurement information may be used to perform the electrochemical modeling through at least one software among a Nyquist diagram, a Bode diagram, a Cole-Cole plot, an impedance phase plot, and an admittance plot.

In one or more embodiments, the impedance analyzer 130 may include a controller configured to control measurement of the impedance value. The controller may be controlled to start or stop the measurement of the impedance value. For example, the impedance analyzer 130 may provide a separate interface to assist in control of the controller.

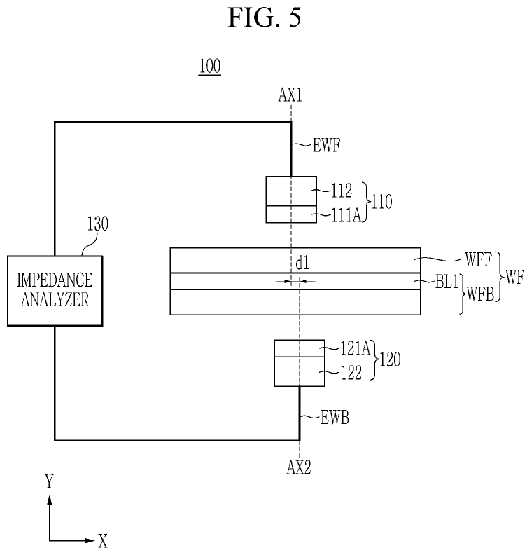

FIG. 5 illustrates a cross-sectional view of the substrate inspection apparatus 100 according to one or more other embodiments of FIG. 2.

Referring to FIG. 5, in one or more embodiments, the first probe 110 and the second probe 120 may be positioned on different vertical axes. For example, a cross-sectional center of the first probe 110 may be placed on a first vertical axis AX1, and a cross-sectional center of the second probe 120 may be placed on a second vertical axis AX2.

More For example, the vertical axes AX1 and AX2 passing through the cross-sectional centers of the first probe 110 and the second probe 120 may be placed at a predetermined interval d1. Even when the vertical axes AX1 and AX2 of the first probe 110 and the second probe 120 are positioned to be spaced apart from each other by the predetermined interval d1, an impedance value due to an electric field or a magnetic field may be calculated and/or obtained. The first probe 110 and the second probe 120 may obtain information about the substrate, such as a bonding strength, by taking multiple measurements at different positions on the substrate WF while being spaced apart by the predetermined distance d1.

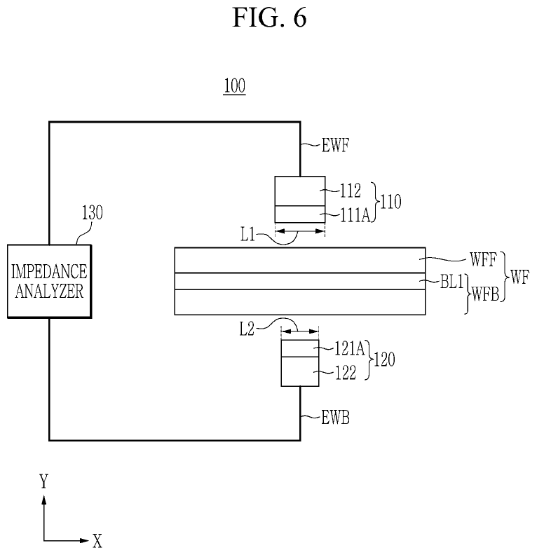

FIG. 6 illustrates a cross-sectional view of the substrate inspection apparatus 100 according to one or more other embodiments of FIG. 2.

Referring to FIG. 6, in one or more embodiments, the first area L1 of the first surface electrode 111A and the second area L2 of the second surface electrode 121A may be different from each other. The first area L1 and the second area L2 may each represent a surface area facing the substrate WF.

For example, the first area L1 and the second area L2 may be different from each other. When the first area L1 and the second area L2 are different, errors or variability in information measured by the first probe 110 and the second probe 120 may be minimized.

In FIG. 6, the first area L1 of the first surface electrode 111A is illustrated as being greater than the second area L2, but embodiments are not limited thereto and, for example, the second area L2 may be greater than the first area L1. In this way, FIGS. 1 to 6 illustrate that the first probe 110 and the second probe 120 may include a first surface electrode 111A and a second surface electrode 121A, but the first surface electrode 111A and the second surface electrode 121A may be replaced with a magnetic material, which will be described later.

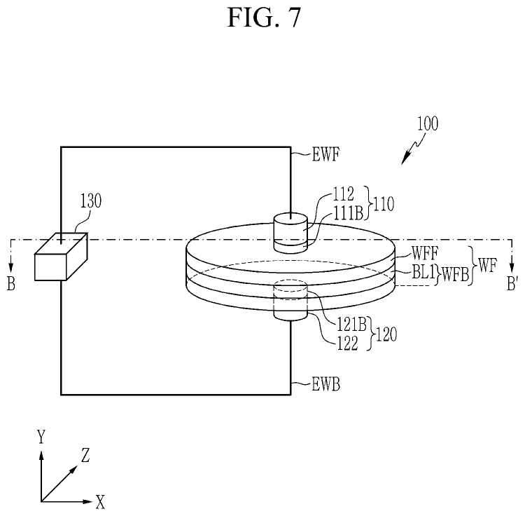

FIG. 7 illustrates a perspective view of a substrate inspection apparatus 100 according to one or more embodiments.

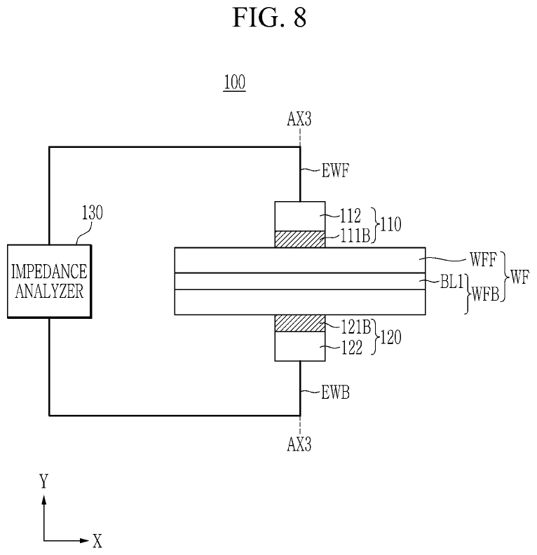

FIG. 8 illustrates a cross-sectional view of the substrate inspection apparatus 100 taken along line BB′ in FIG. 7.

Referring to FIGS. 7 and 8, in one or more embodiments, the substrate inspection device 100 may include a first probe 110 including a first magnetic body 111B, a second probe 120 including a second magnetic body 121B, and the impedance analyzer 130. In comparison with the first probe 110 and the second probe 120 illustrated in FIGS. 1 to 6, the first probe 110 and the second probe 120 of FIG. 7 differ in that they include magnetic bodies 111B and 121B, and for remaining elements, excluding the contents of the magnetic bodies 111B and 121B, reference may be made to the contents described above in FIGS. 1 to 6, to an extent that they do not contradict each other.

The first probe 110 and the second probe 120 may include the first magnetic body 111B and the second magnetic body 121B and the first electrode 112 and the second electrode 122. For example, the first magnetic body 111B may be fixed by the first electrode 112 and the second magnetic body 121B may be fixed by the second electrode 122.

In one or more embodiments, the first probe 110 and the second probe 120 may self-align along a same vertical axis. The first magnetic body 111B and the second magnetic body 121B may exert a magnetic force on each other. For example, the first magnet 111B and the second magnet 121B have different polarities, and thus an attractive force may be exerted.

For example, when the first magnetic body 111B has a N pole, the second magnetic body 121B may have a S pole. In this way, by the attractive force of the first magnetic body 111B and the second magnetic body 121B, the first probe 110 and the second probe 120 may be positioned on the same vertical axis, a third vertical axis AX3, so the first probe 110 and the second probe 120 may be aligned consistently for each measurement, thereby improving measurement accuracy.

In one or more embodiments, the first probe 110 and the second probe 120 may be in contact with the substrate WF. The first probe 110 and the second probe 120 may exchange electrical signals while in contact with the substrate WF by the attractive force of the first magnetic body 111B and the second magnetic body 121B.

The first electrode 112 and the second electrode 122 may be members that connect and fix the first magnetic body 111B and the second magnetic body 121B and assist in allowing a current or a voltage to flow between the first probe 110 and the second probe 120. For example, the first electrode 112 and the second electrode 122 may be coupled and/or connected with the first magnetic body 111B and the second magnetic body 121B to fix the first magnetic body 111B and the second magnetic body 121B, and an AC signal may be applied to the substrate WF to form an electric field or a magnetic field.

In one or more embodiments, the first electrode 112 and the second electrode 122 may be configured as conductors to facilitate a flow of current or voltage between the first probe 110 and the second probe 120. A detailed description of the conductor is the same as that described above in FIGS. 1 and 2, to an extent that it does not contradict.

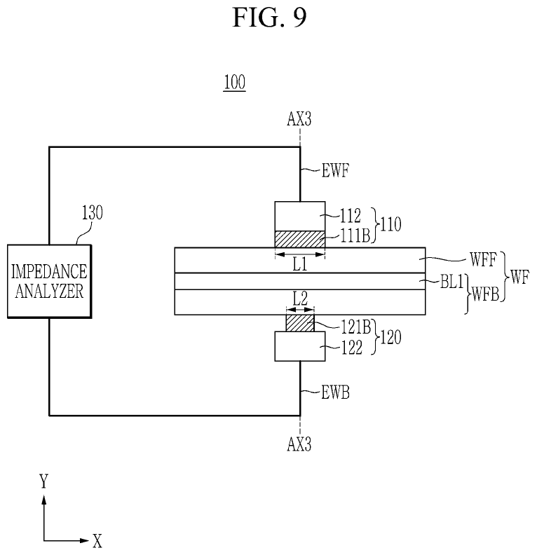

FIGS. 9 to 11 each illustrate a cross-sectional view of the substrate inspection apparatus 100 according to one or more other embodiments of FIG. 8.

Referring to FIG. 9, in one or more embodiments, the first area L1 facing the substrate WF of the first magnetic body 111B and the second area L2 facing the substrate WF of the second magnetic body 121B may be different from each other. The area L1 of the first magnetic body 111B and the area L2 of the second magnetic body 121B facing the substrate WF may be adjusted differently from each other, and as shown in FIG. 9. For example, the second area L2 of the second magnetic body 121B may be implemented to be shorter than the first area L1 of the first magnetic body 111B, thereby minimizing an area in which the second magnetic body 121B contacts the substrate WF, and improving spatial resolution and enhancing precision.

In FIG. 9, a case where the second area L2 of the second magnetic body 121B is shorter than the first area L1 of the first magnetic body 111B is illustrated, but embodiments are not limited thereto. For example, the first area L1 of the first magnetic body 111B may be shorter than the second area L2 of the second magnetic body 121B.

Furthermore, FIG. 9 illustrates a case where lengths of the first area L1 and the second area L2 of the first magnetic body 111B and the second magnetic body 121B in an X-axis direction and the lengths of the first electrode 112 and the second electrode 122 in the X-axis direction are different from each other, but embodiments are not limited thereto. For example, when the surface electrode and the electrode are integrated as a single unit, the surface electrode and the electrode may have the same horizontal length, which may be similarly applied to the cases of FIGS. 1 to 6.

In one or more embodiments, the substrate inspection apparatus 100 may satisfy following Formula 1.

$$0.01 \leq ( L 1 / L 2 ) \times 1000 \leq 10 \qquad < Formula 1 >$$

Here, L1 and L2 represent areas (mm²) of the first magnetic body and the second magnetic body facing the substrate, respectively.

The Formula 1 may be an indicator of spatial resolution as a value 1000 times a value obtained by dividing the first area L1 by the second area L2. The value may be in a range of 0.07 to 8.0. For example, the value may be in a range of 0.78 to 7.9. By satisfying the aforementioned range when dividing by the given value, the contact area of the magnetic body with the substrate WF may be minimized, thereby improving spatial resolution and enhancing precision.

When the value exceeds an upper limit of Formula 1, there may be a problem that a spatial resolution effect is insufficient. When the value exceeds a lower limit of Formula 1, a contact area between a magnetic body with a short length among the magnetic bodies and the substrate may be significantly small, which may cause a problem of loss of electrical signals between the probes, and when an significantly small void exists in a bonding region between the bonding layer BL1 in the substrate WF and the upper substrate WFF, there may be a problem of causing an error in generation of an electric or magnetic field.

Shapes of the first magnetic body 111B and the second magnetic body 121B may include at least one of, for example, a sphere, a cylinder, a cube, a rectangular prism, a cone, or a polygon. As a non-limiting example, the first magnetic body 111B and the second magnetic body 121B may have various shapes, and may be coupled to and/or connected to the first electrode 112 and the second electrode 121.

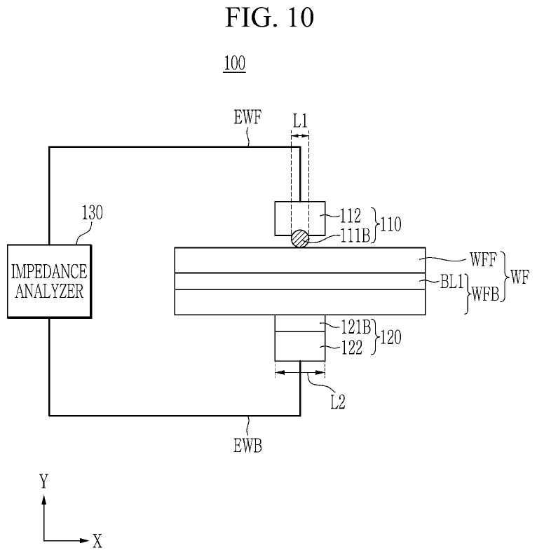

Referring to FIG. 10, in one or more embodiments, the first magnetic body 111B and the second magnetic body 121B may have different shapes. For example, the first magnetic material 111B may have a spherical shape, and the second magnetic material 121B may have a cylindrical shape.

For example, the shape of the first magnetic body 111B has a spherical shape and the shape of the second magnetic body 121B has a cylindrical shape, so a contact area may be reduced for some regions of upper and lower surfaces of the substrate WF, thereby improving a transfer efficiency of the electric signal.

When the first magnetic body 111B has a spherical shape and the second magnetic body 121B has a cylindrical shape, the precision may be improved compared to when both the first magnetic body 111B and the second magnetic body 121B have a cylindrical shape, and the transfer efficiency of the electric signal may be improved compared to when both the first magnetic body 111B and the second magnetic body 121B have a spherical shape.

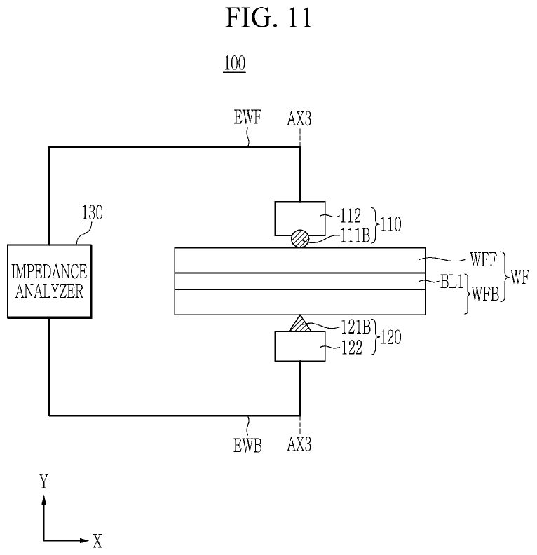

Referring to FIG. 11, in one or more other embodiments, the first magnetic body 111B may have a spherical shape, and the second magnetic body 121B may have a conical shape. In this way, one of the first magnetic body 111B and the second magnetic body 121B may have a cone shape that can minimize an area in contact with the substrate WF, thereby improving a spatial resolution.

In FIGS. 7 to 11, the magnetic body and the electrode are disclosed as separate and independent configurations, but embodiments are not limited thereto, and may be applied to the probe in an integral form in which the magnetic body is integrated with the electrode, thereby inducing an electric field or a magnetic field, and may be a component such as a magnet electrode that enables measurement of impedance.

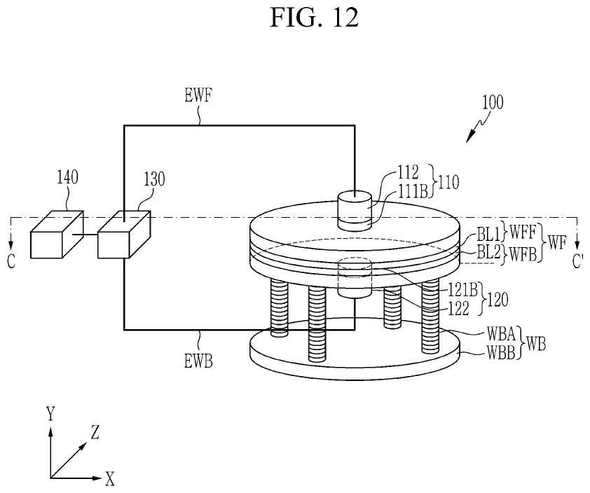

FIG. 12 illustrates a perspective view of a substrate inspection apparatus 100 according to one or more embodiments.

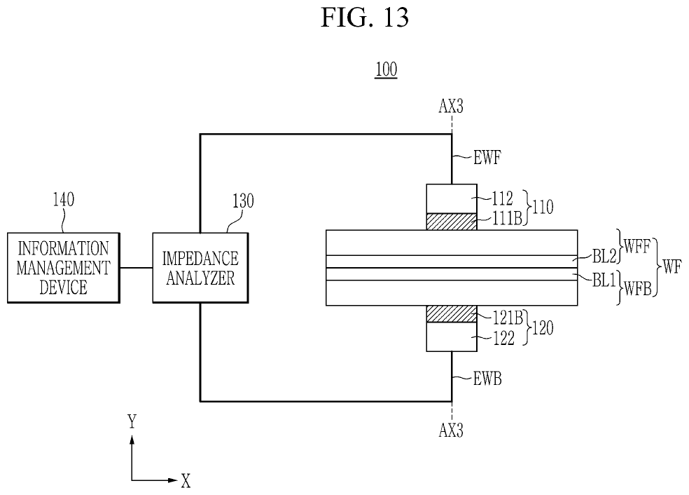

FIG. 13 illustrates a cross-sectional view of the substrate inspection apparatus 100 taken along line CC′ in FIG. 12.

Referring to FIGS. 12 and 13, in one or more embodiments, the substrate inspection apparatus 100 may include a substrate support WB, a first probe 110, a second probe 120, an impedance analyzer 130, and an information management device 140. For detailed information on the first probe 110, the second probe 120, and the impedance analyzer 130, reference may be made to the contents of FIGS. 1 to 11 to an extent that they do not contradict each other.

The substrate support WB may be a member that supports the substrate WF. The substrate support WB may include a clamping pin WBA and a support frame WBB. The clamping pin WBA may be positioned on the support frame WBB to support a lower surface of the lower substrate WFB.

In one or more embodiments, the clamping pin WBA may indicate a member protruding from the substrate frame WBB toward the substrate WF. In FIG. 12, the protruding member is depicted as a rod shape, but embodiments are not limited thereto, and may be implemented in various shapes. Furthermore, although FIG. 12 illustrates three clamping pins WBA arranged on the support frame WBB, embodiments are not limited thereto, and it may also include a case where four or more are arranged.

In one or more embodiments, the substrate WF may include an upper substrate WFF and a lower substrate WFB. For example, the substrate WF may include a plurality of bonding layers BL1 and BL2. More For example, the bonding layers BL1 and BL2 may be oxide films having different properties.

For example, the upper substrate WFF may include a second bonding layer BL2 on a lower surface thereof, and the lower substrate WFB may include a first bonding layer BL1 on an upper surface thereof. For example, the upper substrate WFF and the lower substrate WFB may be bonded by the second bonding layer BL2 and the first bonding layer BL1 to form one substrate WF.

The impedance analyzer 130 may apply an AC signal to the first probe 110 and the second probe 120, and may detect a change in impedance according to a frequency generated from the AC signal. For example, the impedance analyzer 130 may convert measurement information including a change in an impedance into graphics to perform electrochemical modeling. For further detailed description, reference may be made to the foregoing, to an extent that they do not contradict each other.

The information management device 140 may compare and analyze information about a pre-secured substrate and information measured from the impedance analyzer 130 to derive information about the bonding layer between the upper substrate and the lower substrate. The information on the above-mentioned pre-secured substrate may include information such as a bonding strength in a bonding region for the substrate WF that has undergone the same or similar process as the substrate WF that is an inspection target of the substrate inspection apparatus, and it may refer to data that has already been secured. For example, information about the pre-secured substrate may be obtained by performing a process such as a destructive inspection on one region of a plurality of substrates WF subjected to the same process, and may include, for example, information about a bonding strength between the first bonding layer BL1 and the second bonding layer BL2, characteristics of each film, etc.

The information management device 140 may compare and analyze the information obtained for the pre-secured substrate through the aforementioned process with the information acquired from an impedance value measured by the impedance analyzer 130, thereby identifying not only the bonding region within the substrate WF but also physical properties of the bonding layers in the region. For example, information obtained from the impedance value may be information that is diagrammed by modeling measurement information. The diagrammatic information may include various numerical values, such as contact resistance, capacitance, or permittivity, as electrical characteristics of the substrate WF including the bonding region.

In this way, for the substrate WF bonded by a plurality of bonding layers, not only may the bonding strength be directly measured by utilizing the information management device 140, but also physical properties of the first bonding layer BL1 and the second bonding layer BL2 including the bonding region may be measured. Although FIGS. 12 and 13 illustrate the substrate WF bonded by a double bonding layer, embodiments are not limited thereto, and the same may be applied to a substrate bonded by a single bonding layer or multiple bonding layers when utilizing the information management device 140.

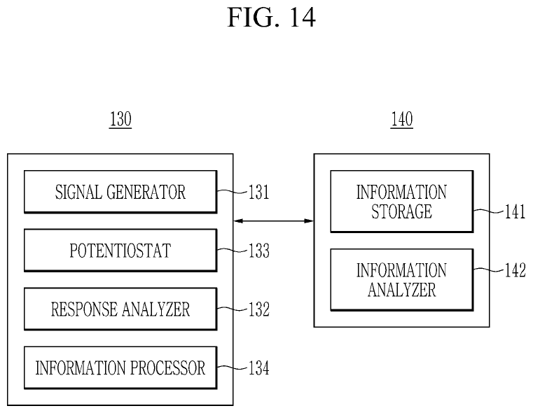

FIG. 14 illustrates a block diagram of the impedance analyzer 130 and the information management device 140 according to one or more embodiments.

Referring to FIG. 14, the impedance analyzer 130 and the information management device 140 may exchange information with each other. For example, the impedance analyzer 130 may provide measurement information to the information management device 140, and the information management device 140 may compare and analyze the measurement information received from the impedance analyzer 130 with previously stored information. A detailed description of the impedance analyzer 130 may be obtained by referring to the contents of FIG. 3 described above, to an extent that they do not contradict each other.

In one or more embodiments, the information management device 140 may include an information storage 141 and an information analyzer 142. The information storage 141 may store information about a pre-secured substrate. For example, the information on the pre-secured substrate may be information on a substrate secured by performing a process such as a destructive inspection on one region of a plurality of substrates WF subjected to a same process as the target substrate to be measured. Information about the secured substrate may include, but is not limited to, examples such as a bonding strength between the upper substrate and the lower substrate and properties of the oxide film as a bonding layer.

For example, the bonding strength between the upper substrate and the lower substrate may vary depending on various factors such as a void in the bonding layer disposed between the upper substrate and the lower substrate, a plasma process condition and plasma distribution, a type and properties of the bonding layer, and a post-process condition such as annealing.

The information analyzer 142 may compare and analyze information about the pre-secured substrate with information measured by the impedance analyzer 130. The information measured by the impedance analyzer 130 may be compared and analyzed based on the information on the pre-secured substrate. For example, factors of the formula may be calculated by substituting information about the pre-secured substrate into a formula derived from electrochemical modeling information derived from information measured by the impedance analyzer 130. The factors of the formula may derive values for various factors described above, as well as, for example, a numerical value of the bonding strength between the upper and lower substrates.

In this way, the information analyzer 142 may directly calculate and/or obtain the bonding strength of the substrate by comparing and analyzing the information about the pre-secured substrate stored in the information storage 141 with the measurement information received from the impedance analyzer 130, and may further directly calculate and/or obtain values for various factors such as contact resistance, capacitance, or a dielectric constant.

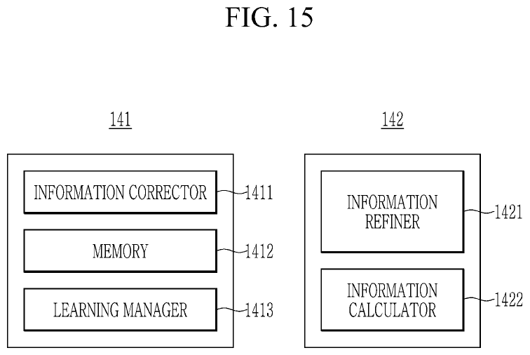

FIG. 15 illustrates a block diagram of the information management device 140 according to one or more embodiments.

Referring to FIG. 15, in one or more embodiments, the information storage 141 may include an information collector 411, a memory 1412, and a learning manager 1413. For example, the information storage 141 may collect information on a pre-secured substrate, store the information, and then use data set to learn an artificial intelligence model.

The information collector 1411 may collect information on the pre-secured substrate. For example, the information collector 1411 may include information such as a bonding strength in a bonding region for the substrate that has undergone the same or similar process as the substrate that is an inspection target of the substrate inspection apparatus, and the information may refer to data that has already been secured. For example, the information about the pre-secured substrate may be information on a substrate secured by performing a process such as a destructive inspection on one region of a plurality of substrates subjected to a same process. Information about the pre-secured substrate may include, but is not limited to, examples such as a bonding strength of the substrate, properties of an oxide film that is a bonding layer that bonds the upper substrate and the lower substrate, etc.

The memory 1412 may store information obtained from the information analyzer 142. For example, the memory 1412 may store the result values compared and analyzed in the information analyzer 142.

The learning manager 1413 may proceed with learning of an artificial intelligence (AI) model using a dataset stored in the memory 1412. For example, the learning manager 1413 may build an artificial intelligence model using a data set that is matched with the information collected in the memory 1412 and received from the information analyzer 142. This may allow for faster prediction of the bonding strength of the substrate WF for various bonding processes. In addition, various information such as the bonding resistance, the capacitance, or the dielectric constant of the substrate may be predicted in addition to the bonding strength.

The artificial intelligence model may be a non-limiting example, and various types of data analysis methods such as big data analytics, deep learning, machine learning, reinforcement learning, Bayesian optimization, simulation optimization, or statistical modeling may be utilized.

In one or more embodiments, the information management device 140 may include an information refiner 1421 and an information calculator 1422. The information management device 140 may compare and analyze measurement information and storage information and calculate modeled information therefrom.

The information refiner 1421 may compare and analyze information stored in the information storage 141 and information collected through the impedance analyzer 130. For example, the information refiner 1421 may determine whether the information collected through the impedance analyzer 130 forms an identical or similar relationship with the information stored in the information storage 141. For example, the information stored in the information storage 141 may become reference information, and whether the information collected through the impedance analyzer 130 is identical to or similar to the reference information may be determined.

The information refiner 1421 may determine that the bonding strength of the substrate is within an appropriate range if the information collected through the impedance analyzer 130 is identical to or similar to the reference information. When the information collected through the impedance analyzer 130 is significantly different from the average value of the reference information, whether the bonding strength of the substrate is not within the appropriate range may be determined. In this way, the information refiner 1421 may refine data that is significantly different from the information collected through the impedance analyzer 130 and the information when the reference information is identical or similar, and transmit the data to the information calculator 1422.

The information calculator 1422 may calculate and/or obtain information about the substrate based on data received from the information refiner 1421. For example, factors of the formula may be calculated and/or obtained by substituting information about the pre-secured substrate into a formula derived from electrochemical modeling information for refined data. The factors of the formula may derive values for various factors described above, as well as, for example, a numerical value of the bonding strength between the upper and lower substrates.

For example, a formula may be derived from a Nyquist diagram derived from the impedance analyzer 130. For the formula, strategic numerical values may be derived for various factors by calculating with the reference information value. Through this, it may be possible to verify whether the bonding strength of the substrate has been appropriately controlled based on the refined information obtained from the information refinement and matching device 1421. Additionally, a result value calculated and/or obtained from the information calculator 1422 may be passed to the information storage 141 for learning of an artificial intelligence model.

In this way, the substrate inspection apparatus 100 according to one or more embodiments may calculate and/or obtain information about the substrate using the information about the pre-secured substrate and the information received from the impedance analyzer 130 in the information analyzer 142, thereby quantitatively digitizing information about various factors as well as the bonding strength of the substrate. Furthermore, the substrate inspection apparatus 100 according to one or more embodiments may further transmit information calculated and/or obtained by the information calculator 1422 back to the information storage 141 and perform learning of an artificial intelligence model in the learning manager 1413, thereby enabling prediction of information on a bonding strength and various other factors when performing inspection of the substrate.

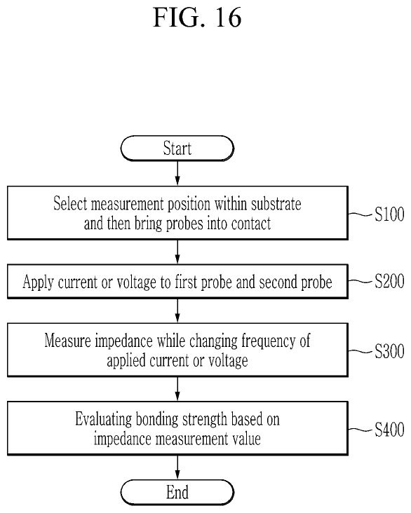

FIG. 16 illustrates a flowchart of a substrate inspection method according to one or more embodiments.

Referring to FIG. 16, a substrate inspection method according to one or more embodiments may include an operation of selecting a measurement position within a substrate and then bringing probes into contact (S100), an operation of applying a current or a voltage to a first probe and a second probe (S200), an operation of measuring impedance while changing a frequency of the applied current or voltage (S300), and an operation of evaluating a bonding strength based on an impedance measurement value (S400). The substrate inspection method according to one or more embodiments may be performed by the substrate inspection apparatus described above, and may evaluate the bonding strength of the substrate including a bonding region through a non-destructive method.

The operation of contacting the probes (S100) may involve placing them separately on an upper portion and a lower portion of the substrate to which a plurality of substrates are bonded. For example, a preparatory operation for performing electrochemical spectroscopy may be performed by placing a first probe on the upper portion of the substrate and a second probe on the lower portion of the substrate.

The operation of applying the current or voltage to the first probe and the second probe (S200) may involve applying an AC signal from the impedance analyzer to the first probe and the second probe. The AC signal may be, e.g., an AC current or an AC voltage. An electric field or a magnetic field may be formed between the first probe and the second probe by applying the current or voltage to the first probe and the second probe.

The operation of measuring the impedance while changing the frequency of the applied current or voltage (S300) may involve detecting a change in impedance according to a frequency generated from the AC current or AC voltage. For example, the impedance may be calculated and/or by measuring a response of the current to voltage applied to the first and second probes. Thereafter, by repeating the measurement while changing a frequency of the applied AC signal, the impedance at various frequencies may be measured to analyze a frequency response characteristic.

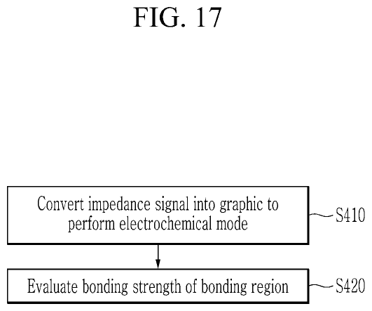

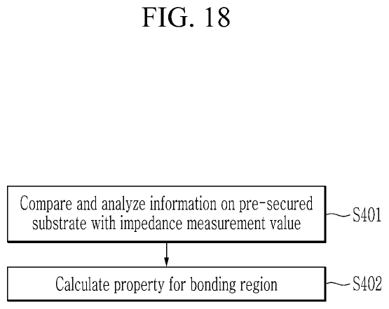

FIGS. 17 and 18 illustrate detailed flowcharts of an operation for evaluating a bonding strength of a bonding region according to various embodiments according to one or more embodiments.

Referring to FIG. 17, the operation of evaluating the bonding strength based on the impedance measurement value (S400) may involve an operation of converting an impedance signal into a graphic to perform electrochemical modeling (S410) and an operation of evaluating the bonding strength of the bonding region (S420).

The operation of converting the impedance signal into the graphic to perform the electrochemical modeling may involve performing the electrochemical modeling by converting the impedance signal at various frequencies into a graphic. The electrochemical modeling may be visualized by modeling by at least one of a Nyquist diagram, a Bode diagram, a Cole-Cole plot, an impedance phase plot, or an admittance plot.

For example, when the electrochemical modeling utilizes the Nyquist diagram, real and imaginary components from the impedance may be utilized to diagram the Nyquist diagram.

The operation of evaluating the bonding strength of the bonding region (S420) may involve evaluating the bonding strength of the substrate based on the modeled result. For example, in the Nyquist diagram, when the bonding strength of the substrate is ideal, a contact resistance of the bonding layer may decrease, thereby reducing a radius of the semi-circle.

In this way, measurement information according to impedance may be graphically modeled, and the bonding strength of the substrate may be indirectly evaluated based on a specific factor within the graphic.

Referring to FIG. 18, in one or more other embodiments, the operation of evaluating the bonding strength based on the impedance measurement value may include an operation of comparing and analyzing the information on the pre-secured substrate with the impedance measurement value (S401) and an operation of calculating and/or obtaining a property for the bonding region (S402).

The operation of comparing and analyzing the information on the pre-secured substrate with the impedance measurement value (S401) may involve determining whether the impedance measurement value has an appropriate bonding strength based on the information about the pre-secured substrate. The information on the pre-secured substrate may include information such as a bonding strength in a bonding region for the substrate that has undergone the same or similar process as the substrate that is an inspection target of the substrate inspection apparatus, and the information may refer to data that has already been secured. For example, the information about the pre-secured substrate may be information on a substrate secured by performing a process such as a destructive inspection on one region of a plurality of substrates subjected to a same process, information such as the bonding strength of the substrate, and further information on a film quality of the bonding layer.

The impedance measurement value may refer to information that is diagrammed by modeling measurement information according to impedance. For example, the impedance measurement value may be a formula calculated from the diagrammed information.

Based on the information about the pre-secured substrate, numerical values for various factors of the formula may be calculated and/or obtained, and thereby derive quantitative numerical values for the various factors. The various factors may be factors such as, e.g., the bonding strength of the substrate, the bonding resistance, the capacitance, or the permittivity.

The operation of calculating and/or obtaining the property for the bonding region may involving derive the various factors described above as quantitative numerical values. In this way, the substrate inspection method may measure the impedance values of the substrate using probes, compare and analyze the derived values with the information obtained for the pre-secured substrate, and quantitatively calculate and/or obtain the bonding strength rather than relying on an indirect evaluation, thereby enhancing precision of bonding strength. Furthermore, the substrate inspection method may quantitatively calculate and/or obtain various other factors about the substrate, so various information about the substrate may be utilized.

The substrate inspection method according to one or more embodiments may be performed by the substrate inspection device described above in FIGS. 1 to 15, and reference may be made to the above-described contents in FIG. 1 to FIG. 15 to an extent that they do not contradict each other.

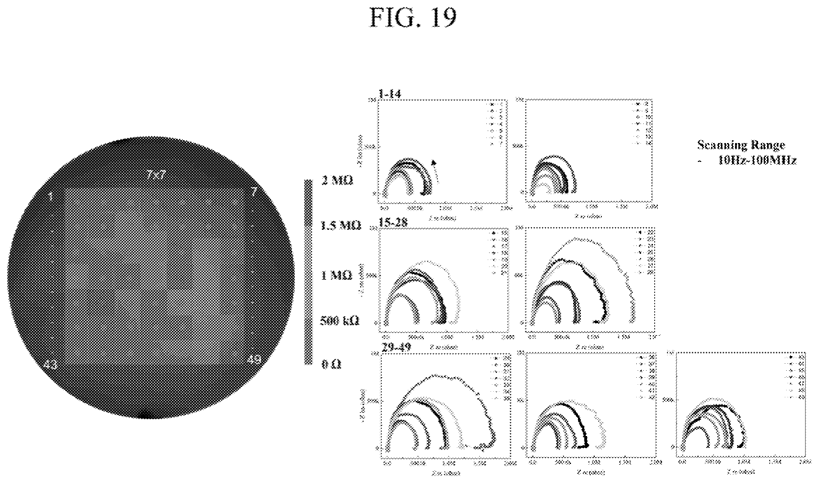

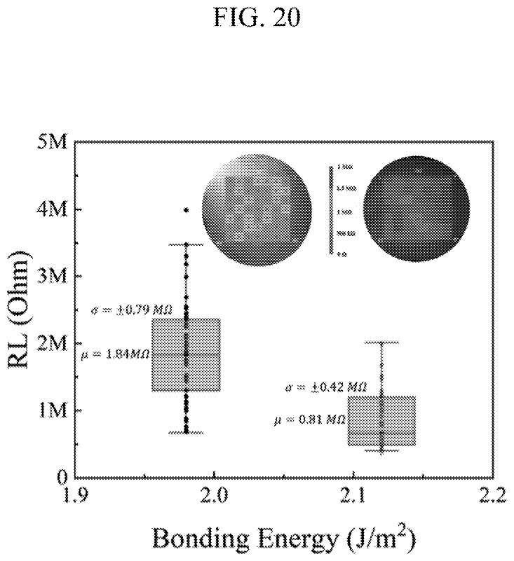

FIGS. 19 and 20 illustrate data on bonding strength evaluation results according to a substrate inspection apparatus or a substrate inspection method according to one or more embodiments.

FIG. 19 illustrates data by the substrate inspection apparatus or the substrate inspection method according to one or more embodiments. For example, the data was measured by placing a first probe and a second probe at 49 positions on an oxide film bonding substrate.

For example, the first probe was placed in upper portions, while the second probe was placed in lower portions at positions 1 to 49. Thereafter, the impedance was measured by applying a voltage or current while changing the frequency from a low frequency to a high frequency through the probes. Thereafter, the Nyquist diagram was plotted using the real and imaginary components of the measured impedance signal.

In this case, as a bonding surface quality of the substrate becomes more ideal, a contact resistance R_{L} of the bonded region decreases. This is represented as a reduction in a radius of the semi-circle observe and/or operated in the Nyquist diagram when visualized from a perspective of the circuit model, and a wafer bonding strength was evaluated based on the corresponding signal values at each measurement position.

In a case of FIG. 19, the bonding layer, which is an oxide film, has a significantly low bonding strength at positions 33 and 37 where the bonding strength is 2 MΩ or more.

FIG. 20 illustrates a correlation between the bonding strength of the substrate and the contact resistance R_{L} extracted through electrochemical spectroscopy. For example, in FIG. 20, a higher contact resistance value derived from FIG. 19 indicates and corresponds to a lower bonding strength of the substrate, whereas a lower contact resistance value indicates and corresponds to a higher bonding strength.

At least one of the components, elements, modules or units (collectively “components” in this paragraph) represented by a block or an equivalent indication in the drawings including FIGS. 1-15 may be implemented or embodied by analog and/or digital circuits including one or more of a logic gate, an integrated circuit, a microprocessor, a microcontroller, a memory circuit, a passive electronic component, an active electronic component, an optical component, and the like. Alternatively or additionally, these components may be implemented or embodied by software including one or more instructions stored in an internal or external storage medium that is readable by at least one processor. For example, the at least one processor may invoke at least one of the one or more instructions stored in the storage medium, and execute it, with or without using one or more other components under the control of the at least one processor. This allows the at least one processor to perform at least one function or operation described above as being performed by each of the components according to the at least one instruction invoked. Here, the at least one processor may include a central processing unit (CPU), a graphic processing unit (GPU), another type of microprocessor, not being limited thereto.

While embodiments have been described with reference to the figures, it will be understood by those of ordinary skill in the art that various changes in form and details may be made therein without departing from the spirit and scope as defined by the following claims and their equivalents.

What is claimed is:

1. A substrate inspection apparatus configured to inspect a substrate, the substrate inspection apparatus comprising:
a first probe on an upper portion of the substrate;
a second probe on a lower portion of the substrate opposite to the first probe, a polarity of the second probe being opposite to a polarity of the first probe; and
an impedance analyzer configured to measure an impedance by at least one of a current applied to the first probe and the second probe and a voltage applied to the first probe and the second probe.

2. The substrate inspection apparatus of claim 1, wherein the first probe comprises a first surface electrode and the second probe comprises a second surface electrode, and
wherein a polarity of the first surface electrode is different from a polarity of the second surface electrode.

3. The substrate inspection apparatus of claim 1, wherein the first probe and the second probe are placed on different vertical axes.

4. The substrate inspection apparatus of claim 2, wherein an area of the first surface electrode facing the substrate is different from an area of the second surface electrode facing the substrate.

5. The substrate inspection apparatus of claim 1, wherein the impedance analyzer is configured to:
apply an alternating current (AC) signal to the first probe and the second probe, and
detect a change in an impedance based on a frequency generated from the AC signal.

6. The substrate inspection apparatus of claim 5, wherein the impedance analyzer is further configured to convert measurement information that comprises the change in the impedance into a graphic to perform electrochemical modeling.

7. The substrate inspection apparatus of claim 1, further comprising
an information management and analyzer configured to compare and analyze information about a pre-secured substrate and information measured from the impedance analyzer to obtain information about a bonding layer between an upper substrate and a lower substrate of the substrate,
wherein the information management and analyzer comprises:
an information storage configured to store information about the pre-secured substrate; and
an information analyzer configured to compare and analyze information about the pre-secured substrate with information measured by the impedance analyzer.

8. The substrate inspection apparatus of claim 7, wherein the information storage comprises:
an information collector configured to collect information about the pre-secured substrate;
a memory configured to store information analyzed from the information analyzer; and
a learning manager configured to perform learning of an artificial intelligence model based on a dataset stored in the memory.

9. The substrate inspection apparatus of claim 8, wherein the information analyzer comprises:
an information refiner configured to compare and analyze information stored in the information storage and information collected through the impedance analyzer; and
an information calculator configured to obtain information about the substrate based on information compared and analyzed from the information refiner.

10. A substrate inspection apparatus configured to inspect a substrate, the substrate inspection apparatus comprising:
a first probe on an upper portion of the substrate and configured to comprise a first magnetic body having magnetism;
a second probe on a lower portion of the substrate opposite to the first probe, the second probe being configured to have a second magnetic body having magnetism opposite to the magnetism of the first magnetic body; and
an impedance analyzer configured to measure an impedance by at least one of a current applied to the first probe and the second probe and a voltage applied to the first probe and the second probe,
wherein the first probe and the second probe are self-aligned along a same vertical axis.

11. The substrate inspection apparatus of claim 10, wherein the first probe comprises:
the first magnetic body; and
a first electrode connected to the first magnetic body,
wherein the second probe comprises a second electrode coupled with the second magnetic body, and
wherein a shape of the first magnetic body and a shape the second magnetic body comprises at least one of a sphere, a cylinder, a cube, a rectangular prism, a cone, or a polyhedron.

12. The substrate inspection apparatus of claim 11, wherein the first magnetic body has a spherical shape, and
wherein the second magnetic body has a cylindrical shape.

13. The substrate inspection apparatus of claim 10, wherein the first magnetic body and the second magnetic body satisfy:
$$0.01 \leq ( L 1 / L 2 ) \times 1000 \leq 10 ,$$
where L1 is an area (mm²) of the first magnetic body facing the substrate and L2 is an area (mm²) of the second magnetic body facing the substrate.

14. The substrate inspection apparatus of claim 10, wherein the first probe and the second probe each comprises a first driver and a second driver configured to move the first probe and the second probe in a vertical direction, respectively.

15. The substrate inspection apparatus of claim 10, wherein the impedance analyzer comprises:
a signal generator configured to generate an alternating current (AC) signal;
a frequency response analyzer configured to detect a change in the impedance based on a frequency generated from the signal generator; and
an information processor configured to process and analyze information measured through the frequency response analyzer.

16. A substrate inspection apparatus for inspecting a substrate, the substrate inspection apparatus comprising:
a substrate support configured to support the substrate;
a first probe on an upper portion of the substrate;
a second probe on a lower portion of the substrate opposite to the first probe, a polarity of the second probe being different from a polarity of the first probe;
an impedance analyzer configured to apply an alternating current (AC) signal to the first probe and the second probe and detect a change in an impedance based on a frequency generated from the AC signal; and
an information management and analyzer configured to compare and analyze information about a pre-secured substrate and information measured from the impedance analyzer to obtain information about a bonding layer between an upper substrate and a lower substrate included in the substrate.

17. The substrate inspection apparatus of claim 16, wherein the impedance analyzer is configured to:
apply an AC signal to the first probe and the second probe, and
detect a change in an impedance based on the frequency generated from the AC signal.

18. The substrate inspection apparatus of claim 17, wherein the impedance analyzer is further configured to convert the information measured into a graphic to perform modeling as a Nyquist diagram.

19. The substrate inspection apparatus of claim 16, wherein the information management and analyzer is further configured to compare and analyze information about a pre-secured substrate with information measured by the impedance analyzer to establish a learning model by at least one of big data analytics, deep learning, machine learning, reinforcement learning, Bayesian optimization, simulation optimization, or statistical modeling.

20. The substrate inspection apparatus of claim 16, wherein the first probe comprises a first magnetic body, a first electrode connected to the first magnetic body, and a first driver driving the first probe, and
wherein the second probe comprises a second magnetic body, a second electrode connected to the second magnetic body, and a second driver.
